(19) United States
(12) Patent Application Publication
(10) Pub. No.: US 2025/0331367 A1
(43) Pub. Date: Oct. 23, 2025

(54) DISPLAY DEVICE AND ELECTRONIC DEVICE

(71) Applicant: Samsung Display Co., LTD., Yongin-si (KR)

(72) Inventors: KOHEI EBISUNO, Yongin-si (KR); DONGHYEOK LEE, Yongin-si (KR); MOOSOON KO, Yongin-si (KR); SE WAN SON, Yongin-si (KR); YONGHO YANG, Yongin-si (KR); KWANHEE LEE, Yongin-si (KR); JAESOO JUNG, Yongin-si (KR); Yoonah CHOI, Yongin-si (KR); YOUNG-IN HWANG, Yongin-si (KR)

(21) Appl. No.: 19/065,314

(22) Filed: Feb. 27, 2025

(30) Foreign Application Priority Data
Apr. 18, 2024 (KR) 10-2024-0052083

(51) Int. Cl. H10K 59/122; H10K 50/19; H10K 102/00

(52) U.S. Cl. CPC H10K 59/122; H10K 50/19; H10K 2102/351

(57) ABSTRACT

A display device includes a protection pattern disposed on a pixel electrode and defining a first opening exposing the pixel electrode, a first protruding pattern disposed on the protection pattern and defining a second opening exposing the pixel electrode, a second protruding pattern disposed on the first protruding pattern, defining a third opening exposing the pixel electrode and protruding further toward a center of the pixel electrode than the first protruding pattern, and a common electrode disposed on the second protruding pattern.

This application claims priority to Korean Patent Application No. 10-2024-0052083, filed on Apr. 18, 2024, and all the benefits accruing therefrom under 35 U.S.C. § 119, the content of which in its entirety is herein incorporated by reference.

### BACKGROUND

### 1. Field

The invention relates to a display device and, more specifically, to a display device that provides visual information and an electronic device including the display device.

### 2. Description of the Related Art

A display device may be formed by stacking a plurality of layers such as a metal layer, an insulating layer, a light emitting layer, or the like, together, where some layers of the plurality of layers may be provided in common with a plurality of pixels. When some of the layers function as a charge transfer path, a current supplied to one pixel may also be supplied to adjacent pixels, thereby resulting in leakage current. By this leakage current, pixels of different colors disposed adjacent to each other may be driven to cause color mixing.

### SUMMARY

Embodiments provide a display device with improved display quality.

Embodiments provide an electronic device including the display device.

A display device, according to an embodiment, includes a protection pattern disposed on a pixel electrode and defining a first opening exposing the pixel electrode, a first protruding pattern disposed on the protection pattern and defining a second opening exposing the pixel electrode, a second protruding pattern disposed on the first protruding pattern, defining a third opening exposing the pixel electrode, and protruding further toward a center of the pixel electrode than the first protruding pattern, and a common electrode disposed on the second protruding pattern.

In an embodiment, the first protruding pattern and the second protruding pattern may include different inorganic materials.

In an embodiment, the first protruding pattern may include silicon nitride, and the second protruding pattern may include silicon oxide.

In an embodiment, the protection pattern may include at least one selected from a group consisting of a metal, an alloy, and a transparent conductive material.

In an embodiment, the first protruding pattern may protrude further toward the center of the pixel electrode than the protection pattern.

In an embodiment, the protection pattern, the first protruding pattern, and the second protruding pattern may be disposed along an edge of the pixel electrode in a plan view.

In an embodiment, the protection pattern, the first protruding pattern, and the second protruding pattern may not overlap at least a portion of the edge of the pixel electrode in the plan view.

In an embodiment, the display device may further include a pixel defining layer disposed between the second protruding pattern and the common electrode, wherein the pixel defining layer defines a fourth opening exposing the pixel electrode, and includes an organic material.

In an embodiment, a thickness of the protection pattern may be in a range of about 100 Å to about 300 Å.

In an embodiment, a thickness of the first protruding pattern may be in a range of about 100 Å to about 3000 Å.

In an embodiment, a thickness of the second protruding pattern may be in a range of about 100 Å to about 1000 Å.

In an embodiment, the display device may further include an intermediate layer disposed between the second protruding pattern and the common electrode, wherein the intermediate layer includes a charge generation layer.

In an embodiment, the charge generation layer may be disconnected by the first protruding pattern and the second protruding pattern.

In an embodiment, the intermediate layer may include a first light emitting layer disposed below the charge generation layer, and a second light emitting layer disposed on the charge generation layer.

A display device, according to an embodiment, includes a protection pattern disposed on a pixel electrode and defining a first opening exposing the pixel electrode, a protruding pattern disposed on the protection pattern, defining a second opening exposing the pixel electrode and protruding further toward a center of the pixel electrode than the protection pattern, a pixel defining layer disposed on the protruding pattern and defining a third opening exposing the pixel electrode, and a common electrode disposed on the pixel defining layer.

In an embodiment, the protruding pattern may include an inorganic material.

In an embodiment, the protection pattern may include at least one selected from a group consisting of a metal, an alloy, and a transparent conductive material.

In an embodiment, the protection pattern and the protruding pattern may be disposed along an edge of the pixel electrode in a plan view.

In an embodiment, the protection pattern and the protruding pattern may not overlap at least a portion of the edge of the pixel electrode in the plan view.

In an embodiment, a thickness of the protection pattern may be in a range of about 100 Å to about 3000 Å.

In an embodiment, a thickness of the protruding pattern may be in a range of about 100 Å to about 1000 Å.

In an embodiment, the pixel defining layer may include an organic material.

In an embodiment, the display device may further include an intermediate layer disposed between the protruding pattern and the common electrode and including a charge generation layer.

In an embodiment, the charge generation layer may be disconnected by the protection pattern and the protruding pattern.

In an embodiment, the intermediate layer may include a first light emitting layer disposed below the charge generation layer and a second light emitting layer disposed on the charge generation layer.

An electronic device, according to an embodiment, includes a display device and a power module that supplies power to the display device. The display device includes a protection pattern disposed on a pixel electrode and defining a first opening exposing the pixel electrode, a first protruding pattern disposed on the protection pattern and defining a second opening exposing the pixel electrode, a second protruding pattern disposed on the first protruding pattern, defining a third opening exposing the pixel electrode, and protruding further toward a center of the pixel electrode than the first protruding pattern, and a common electrode disposed on the second protruding pattern.

In a display device, according to an embodiment, the display device may include a protection pattern and at least one protruding pattern, each exposing at least a portion of a pixel electrode. The protruding pattern may protrude further toward a center of the pixel electrode than the protection pattern, and an intermediate layer may be disconnected by a shape of the protection pattern and/or the protruding pattern. Accordingly, leakage current that may occur between pixels disposed adjacent to each other may be minimized, thereby minimizing color mixing between pixels. In addition, since the protruding pattern includes an inorganic material, a path through which gas generated from an organic material included in a lower insulating layer flows into the intermediate layer may be blocked. Accordingly, deterioration of a light emitting element and pixel shrinkage may be prevented.

### BRIEF DESCRIPTION OF THE DRAWINGS

FIG. 1 is a plan view illustrating a display device, according to an embodiment.

FIG. 2 is an enlarged plan view of a portion of a display area of the display device of FIG. 1, according to an embodiment.

FIG. 3 is a cross-sectional view taken along line I-I′ of the display device of FIG. 2, according to an embodiment.

FIG. 4 is a cross-sectional view illustrating an example of an intermediate layer included in the display device of FIG. 1, according to an embodiment.

FIG. 5 is a cross-sectional view illustrating a method of manufacturing a display device, according to an embodiment.

FIG. 6 is a cross-sectional view illustrating a method of manufacturing a display device, according to an embodiment.

FIG. 7 is a cross-sectional view illustrating a method of manufacturing a display device, according to an embodiment.

FIG. 8 is a cross-sectional view illustrating a method of manufacturing a display device, according to an embodiment.

FIG. 9 is a cross-sectional view illustrating a method of manufacturing a display device, according to an embodiment.

FIG. 10 is a cross-sectional view illustrating a method of manufacturing a display device, according to an embodiment.

FIG. 11 is a cross-sectional view illustrating a display device, according to an embodiment.

FIG. 12 is a plan view illustrating a display device, according to an embodiment.

FIG. 13 is a cross-sectional view taken along line II-II′ of the display device of FIG. 12, according to an embodiment.

FIG. 14 is a cross-sectional view taken along line III-III′ of the display device of FIG. 12, according to an embodiment.

FIG. 15 is a plan view illustrating a display device, according to an embodiment.

FIG. 16 is a cross-sectional view taken along line IV-IV′ of the display device of FIG. 15, according to an embodiment.

FIG. 17 is a cross-sectional view illustrating a method of manufacturing a display device, according to an embodiment.

FIG. 18 is a cross-sectional view illustrating a method of manufacturing a display device, according to an embodiment.

FIG. 19 is a cross-sectional view illustrating a method of manufacturing a display device, according to an embodiment.

FIG. 20 is a cross-sectional view illustrating a method of manufacturing a display device, according to an embodiment.

FIG. 21 is a cross-sectional view illustrating a method of manufacturing a display device, according to an embodiment.

FIG. 22 is a plan view illustrating a display device, according to an embodiment.

FIG. 23 is a cross-sectional view taken along line V-V′ of the display device of FIG. 22, according to an embodiment.

FIG. 24 is a cross-sectional view taken along line VI-VI′ of the display device of FIG. 22, according to an embodiment.

FIG. 25 is a block diagram illustrating an electronic device, according to an embodiment.

FIG. 26 is a schematic view illustrating electronic devices, according to embodiments.

### DETAILED DESCRIPTION

Hereinafter, embodiments of the invention will be described in more detail with reference to the accompanying drawings. The same reference numerals are used for the same components in the drawings, and redundant descriptions of the same components will be omitted.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” may include all combinations of one or more of which associated configurations may define.

It will also be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

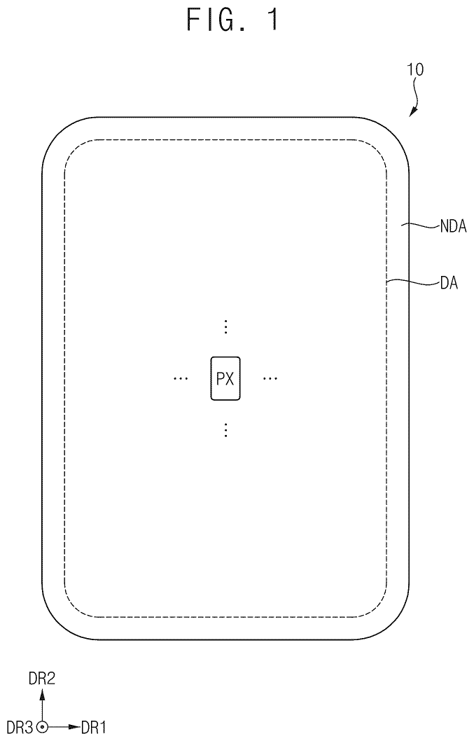

FIG. 1 is a plan view illustrating a display device 10 according to an embodiment of the invention.

In an embodiment and referring to FIG. 1, the display device 10 may include a display area DA and a non-display area NDA.

The display area DA may be an area that displays an image, where a plurality of pixels PX may be disposed in the display area DA. The pixels PX may be repeatedly arranged along a first direction DR1 and a second direction DR2 intersecting the first direction DR1 in a plan view. For example, the second direction DR2 may be in a direction that is perpendicular to the first direction DR1. Each of the pixels PX may display light.

In an embodiment, signal lines such as gate lines, data lines, or the like may be disposed in the display area DA. The signal lines may be connected to each of the pixels PX which may receive gate signals, data signals, or the like from the signal lines. Accordingly, for example, an image may be displayed in the display area DA to be directed in a third direction DR3 intersecting each of the first direction DR1 and the second direction DR2. For example, the third direction DR3 may be a direction that is perpendicular to each of the first direction DR1 and the second direction DR2.

The non-display area NDA may be an area that does not display an image and that may be disposed around the display area DA. For example, the non-display area NDA may surround the display area DA in a plan view. Drivers for displaying an image of the display area DA may be disposed in the non-display area NDA.

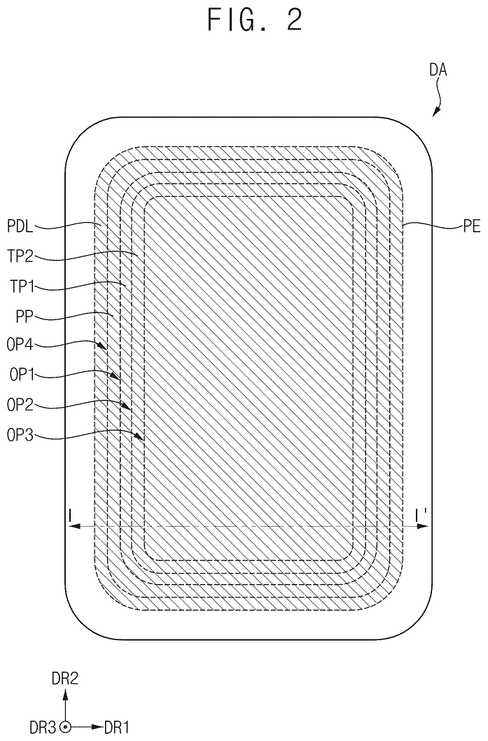

FIG. 2 is an enlarged plan view of a portion of the display area DA of the display device 10 of FIG. 1, according to an embodiment. For example, FIG. 2 may be a plan view schematically illustrating one of the pixels PX disposed in the display area DA of the display device 10.

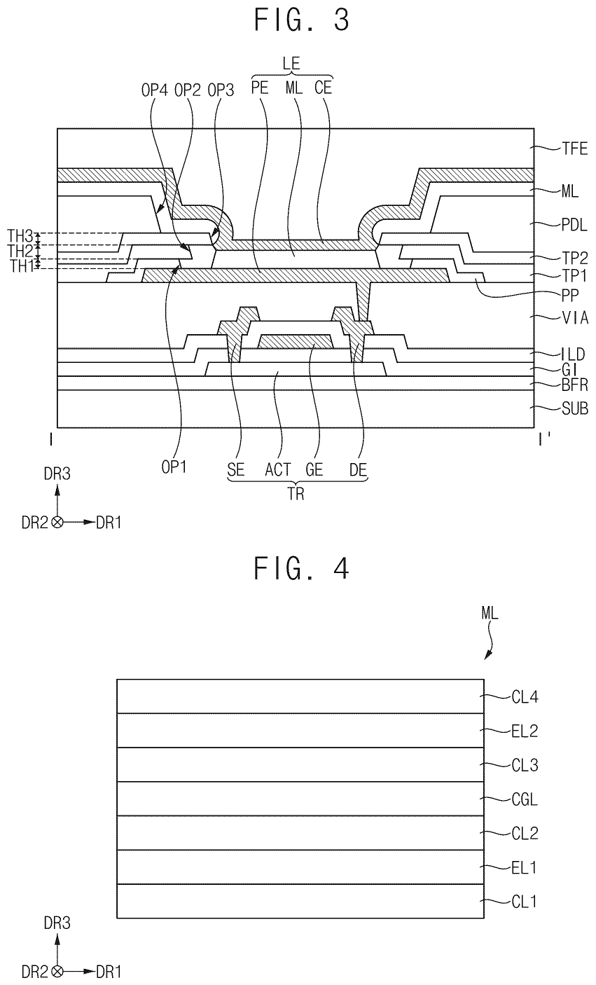

FIG. 3 is a cross-sectional view taken along line I-I′ of FIG. 2, according to an embodiment. FIG. 4 is a cross-sectional view illustrating an example of an intermediate layer ML included in the display device 10 of FIG. 1, according to an embodiment.

In an embodiment and referring to FIGS. 1, 2, 3, and 4, the display device 10 may include a substrate SUB, a buffer layer BFR, a transistor TR, a gate insulating layer GI, an interlayer insulating layer ILD, a via insulating layer VIA, a light emitting element LE, a protection pattern PP, a first protruding pattern TP1, a second protruding pattern TP2, a pixel defining layer PDL, and an encapsulation layer TFE.

In an embodiment, the transistor TR may include an active pattern ACT, a gate electrode GE, a first electrode SE, and a second electrode DE, and the light emitting element LE may include a pixel electrode PE, the intermediate layer ML, and a common electrode CE.

In an embodiment, the substrate SUB may include a transparent material or an opaque material. Examples of materials that may be used as the substrate SUB may include polyimide, quartz, glass, or the like. These may be used alone or in combination with each other.

In an embodiment, the buffer layer BFR may be disposed on the substrate SUB, where the buffer layer BFR may prevent metal atoms, impurities, or the like from diffusing into the transistor TR. In addition, the buffer layer BFR may improve a flatness of a surface of the substrate SUB when the surface of the substrate SUB is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

In an embodiment, the active pattern ACT may be disposed on the buffer layer BFR and may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

In an embodiment, the gate insulating layer GI may be disposed on the active pattern ACT, and may cover the active pattern ACT. The gate insulating layer GI may include an inorganic material such as silicon oxide, silicon nitride, silicon oxynitride, or the like. These may be used alone or in combination with each other.

In an embodiment, the gate electrode GE may be disposed on the gate insulating layer GI and may overlap the channel area of the active pattern ACT in a plan view. The gate electrode GE may include a metal, an alloy, a conductive metal nitride, a conductive metal oxide, a transparent conductive material, or the like. These may be used alone or in combination with each other.

In an embodiment, the interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

In an embodiment, the first electrode SE and the second electrode DE may be disposed on the interlayer insulating layer ILD. The first electrode SE may be connected to the source area of the active pattern ACT through a first contact hole penetrating the gate insulating layer GI and the interlayer insulating layer ILD. In addition, the second electrode DE may be connected to the drain area of the active pattern ACT through a second contact hole penetrating the gate insulating layer GI and the interlayer insulating layer ILD. Each of the first electrode SE and the second electrode DE may include a metal, an alloy, a conductive metal nitride, a conductive metal oxide, a transparent conductive material, or the like. These may be used alone or in combination with each other.

Accordingly, the transistor TR including the active pattern ACT, the gate electrode GE, the first electrode SE, and the second electrode DE may be disposed on the substrate SUB.

In an embodiment, the via insulating layer VIA may be disposed on the interlayer insulating layer ILD, and may cover the first electrode SE and the second electrode DE. The via insulating layer VIA may include an organic material such as a phenol resin, an acrylic resin, a polyimide resin, a polyamide resin, a siloxane resin, an epoxy resin, or the like. These may be used alone or in combination with each other.

In an embodiment, the pixel electrode PE may be disposed on the via insulating layer VIA and may be electrically connected to the transistor TR. For example, the pixel electrode PE may be connected to the second electrode DE (or the first electrode SE) through a contact hole penetrating the via insulating layer VIA. The pixel electrode PE may include a metal, an alloy, a conductive metal oxide, a conductive metal nitride, a transparent conductive material, or the like. These may be used alone or in combination with each other.

In an embodiment, the protection pattern PP may be disposed on the pixel electrode PE and may define a first opening OP1 exposing at least a portion of the pixel electrode PE. The protection pattern PP may be disposed along an edge of the pixel electrode PE in a plan view. For example, the protection pattern PP may cover at least a portion of a side portion of the pixel electrode PE and may serve to minimize damage to the pixel electrode PE during a manufacturing process of the display device 10.

In an embodiment, the protection pattern PP may include a transparent conductive material. For example, the protection pattern PP may include indium gallium zinc oxide (IGZO), indium tin oxide (ITO), indium zinc oxide (IZO), or the like.

In an embodiment, the protection pattern PP may include a material having an etch selectivity that is different from that of the pixel electrode PE. The protection pattern PP may include a metal, an alloy, or the like having an etch selectivity that is different from that of the pixel electrode PE. For example, the protection pattern PP may include a material having an etch selectivity that is higher than that of the pixel electrode PE with respect to an etchant that may be used when forming the protection pattern PP (i.e., when patterning the protection pattern PP). For example, the protection pattern PP may include aluminum (Al), molybdenum (Mo), an alloy including aluminum, an alloy including molybdenum, or the like.

In an embodiment, the protection pattern PP may include aluminum, and the pixel electrode PE may include a material (e.g., indium tin oxide, or the like) having an etch selectivity that is lower than that of the protection pattern PP with respect to an etchant that may be used when forming the protection pattern PP (e.g., an alkaline etchant such as an etchant including potassium hydroxide (KOH), or the like).

In another embodiment, the protection pattern PP may include molybdenum, and the pixel electrode PE may include a material (e.g., indium tin oxide, or the like) having an etch selectivity that is lower than that of the protection pattern PP with respect to an etchant that may be used when forming the protection pattern PP (e.g., a phosphoric acid-based etchant, or the like).

However, the invention is not limited thereto, and the protection pattern PP may include various materials that may be easily formed while preventing damage to the pixel electrode PE during the manufacturing process of the display device 10.

The protection pattern PP may be relatively thin. In an embodiment, a first thickness TH1 of the protection pattern PP may be about 300 Å or less. Here, the first thickness TH1 of the protection pattern PP may be a length of the protection pattern PP directed in the third direction DR3. Preferably, the first thickness TH1 of the protection pattern PP may be in a range of about 100 Å to about 300 Å. For example, when the first thickness TH1 of the protection pattern PP is greater than about 300 Å, damage may occur to a surface of the pixel electrode PE during formation of the protection pattern PP. For example, when the first thickness TH1 of the protection pattern PP is less than about 100 Å, damage may occur to the pixel electrode PE during formation of upper components of the protection pattern PP (e.g., the first protruding pattern TP1 and the second protruding pattern TP2).

However, the invention is not limited thereto, and the first thickness TH1 of the protection pattern PP may be variously modified within a range to prevent damage to the pixel electrode PE during the manufacturing process of the display device 10.

Although FIGS. 2 and 3 illustrate an embodiment where the protection pattern PP covers a portion of an upper surface (e.g., an edge of the upper surface) and a side surface of the pixel electrode PE, the invention is not limited thereto. For example, in another embodiment, the protection pattern PP may cover only a portion of the upper surface of the pixel electrode PE.

In an embodiment, the first protruding pattern TP1 may be disposed on the protection pattern PP and may define a second opening OP2 exposing at least a portion of the pixel electrode PE. The second opening OP2 may be connected to the first opening OP1. The first protruding pattern TP1 may be disposed along the edge of the pixel electrode PE in a plan view.

In an embodiment, the first protruding pattern TP1 may protrude further toward a center of the pixel electrode PE than the protection pattern PP. A side surface of the first protruding pattern TP1 defining the second opening OP2 may protrude further toward the center of the pixel electrode PE than a side surface of the protection pattern PP defining the first opening OP1. A planar area of the second opening OP2 may be smaller than a planar area of the first opening OP1. For example, the first protruding pattern TP1 may cover an upper surface of the protection pattern PP.

In an embodiment, the first protruding pattern TP1 may include an inorganic material. For example, the first protruding pattern TP1 may include silicon nitride (SiNₓ), but the invention is not limited thereto.

In an embodiment, a second thickness TH2 of the first protruding pattern TP1 may be in a range of about 100 Å to about 3000 Å. Here, the second thickness TH2 of the first protruding pattern TP1 may be a length of the first protruding pattern TP1 directed in the third direction DR3. However, the invention is not limited thereto, and the second thickness TH2 of the first protruding pattern TP1 may be adjusted depending on a material included in the intermediate layer ML, a structure of the intermediate layer ML, or the like. For example, when a thickness of the intermediate layer ML increases (e.g., when a number of layers included in the intermediate layer ML increases), the second thickness TH2 of the first protruding pattern TP1 may exceed about 3000 Å.

In an embodiment, the second protruding pattern TP2 may be disposed on the first protruding pattern TP1 and may define a third opening OP3 exposing at least a portion of the pixel electrode PE. The third opening OP3 may be connected to the first opening OP1 and the second opening OP2. The second protruding pattern TP2 may be disposed along the edge of the pixel electrode PE in a plan view.

In an embodiment, the second protruding pattern TP2 may protrude further toward the center of the pixel electrode PE than the first protruding pattern TP1. A side surface of the second protruding pattern TP2 defining the third opening OP3 may protrude further toward the center of the pixel electrode PE than the side surface of the first protruding pattern TP1 defining the second opening OP2. The side surface of the second protruding pattern TP2 and the side surface of the first protruding pattern TP1 may have a step difference. A planar area of the third opening OP3 may be smaller than the planar area of the second opening OP2. For example, the second protruding pattern TP2 may cover an upper surface of the first protruding pattern TP1. Accordingly, the first protruding pattern TP1 and the second protruding pattern TP2 may form a tip shape (or an eave shape) in a cross-sectional view.

In an embodiment, the second protruding pattern TP2 may include an inorganic material. The second protruding pattern TP2 may include a material different from that of the first protruding pattern TP1. The second protruding pattern TP2 may include a material having an etch selectivity that is different from that of the first protruding pattern TP1. For example, the second protruding pattern TP2 may include a material having an etch selectivity that is lower than that of the first protruding pattern TP1 with respect to an etching gas that may be used when forming the first and second protruding patterns TP1, TP2 (i.e., when patterning the first and second protruding patterns (TP1, TP2)). For example, the second protruding pattern TP2 may include silicon oxide (SiOₓ), but the invention is not limited thereto.

In an embodiment, a third thickness TH3 of the second protruding pattern TP2 may be in a range of about 100 Å to about 1000 Å, but the invention is not limited thereto. Here, the third thickness TH3 of the second protruding pattern TP2 may be a length of the second protruding pattern TP2 directed in the third direction DR3. For example, when the third thickness TH3 of the second protruding pattern TP2 is greater than about 1000 Å, a profile of the second protruding pattern TP2 may affect upper components.

In an embodiment, the pixel defining layer PDL may be disposed on the second protruding pattern TP2 and may define a fourth opening OP4 exposing at least a portion of the pixel electrode PE. The fourth opening OP4 may be connected to the first opening OP1, the second opening OP2, and the third opening OP3. The pixel defining layer PDL may be disposed along the edge of the pixel electrode PE in a plan view. The pixel defining layer PDL may cover the side portion of the pixel electrode PE and may include an organic material such as a polyimide resin, an epoxy resin, a siloxane resin, or the like. These may be used alone or in combination with each other.

In an embodiment, the fourth opening OP4 may further expose at least a portion of the second protruding pattern TP2, where the second protruding pattern TP2 may protrude further toward the center of the pixel electrode PE than the pixel defining layer PDL. The side surface of the second protruding pattern TP2 defining the third opening OP3 may protrude further toward the center of the pixel electrode PE than a side surface of the pixel defining layer PDL defining the fourth opening OP4. A planar area of the fourth opening OP4 may be greater than the planar area of the third opening OP3. In addition, the planar area of the fourth opening OP4 may be greater than the planar area of each of the first opening OP1 and the second opening OP2.

In an embodiment, the intermediate layer ML may be disposed on the pixel electrode PE, the second protruding pattern TP2, and the pixel defining layer PDL. The intermediate layer ML may be disposed on the pixel electrode PE exposed by the first, second, third, and fourth openings OP1, OP2, OP3, and OP4, the second protruding pattern TP2 exposed by the fourth opening OP4, and the pixel defining layer PDL.

The intermediate layer ML may have a multi-layer structure. For example, the intermediate layer ML may include a first common layer CL1, a first light emitting layer EL1, a second common layer CL2, a charge generation layer CGL, a third common layer CL3, a second light emitting layer EL2, and a fourth common layer CL4.

In an embodiment, the first common layer CL1 may have a single-layer structure or a multi-layer structure. For example, the first common layer CL1 may include at least one of a hole injection layer (HIL) and a hole transport layer (HTL).

In an embodiment, the first light emitting layer EL1 may be disposed on the first common layer CL1. The first light emitting layer EL1 may be disposed on the pixel electrode PE exposed by the protection pattern PP, the first and second protruding patterns TP1 and TP2, and the pixel defining layer PDL. The first light emitting layer EL1 may emit light of a specific wavelength band and may include a material that emits the light.

In an embodiment, the second common layer CL2 may be disposed on the first common layer CL1 and the first light emitting layer EL1. The second common layer CL2 may have a single-layer structure or a multi-layer structure. For example, the second common layer CL2 may include an electron transport layer (ETL).

In an embodiment, the charge generation layer CGL may be disposed on the second common layer CL2 and may have a single-layer structure or a multi-layer structure. The charge generation layer CGL may control the charge balance between the first light emitting layer EL1 and the second light emitting layer EL2. For example, the charge generation layer CGL may include an n-type charge generation layer that provides an electron to the first light emitting layer EL1 and a p-type electron generation layer that provides a hole to the second light emitting layer EL2.

In an embodiment, the third common layer CL3 may be disposed on the charge generation layer CGL and may have a single-layer structure or a multi-layer structure. For example, the third common layer CL3 may include a hole transport layer.

In an embodiment, the second light emitting layer EL2 may be disposed on the third common layer CL3 and may overlap the first light emitting layer EL1 in a plan view. That is, the second light emitting layer EL2 may be disposed on the pixel electrode PE exposed by the protection pattern PP, the first and second protruding patterns TP1 and TP2, and the pixel defining layer PDL. The second light emitting layer EL2 may emit light of a specific wavelength band and may include a material that emits the light.

In an embodiment, the fourth common layer CL4 may be disposed on the third common layer CL3 and the second light emitting layer EL2. The fourth common layer CL4 may have a single-layer structure or a multi-layer structure. For example, the fourth common layer CL4 may include at least one of an electron injection layer (EIL) and an electron transport layer.

In an embodiment, the intermediate layer ML may be disconnected by the first and second protruding patterns TP1 and TP2. The intermediate layer ML may be disconnected by the shapes of the first and second protruding patterns TP1 and TP2. The intermediate layer ML may include a first portion disposed on the second protruding pattern TP2 and the pixel defining layer PDL and a second portion disposed on the pixel electrode PE, where the first portion and the second portion may be spaced apart from each other. Accordingly, the intermediate layer ML may be disconnected between the pixels PX disposed adjacent to each other.

For example, the charge generation layer CGL included in the intermediate layer ML may be disconnected by the protruding patterns TP1 and TP2. The charge generation layer CGL may include a first portion disposed on the second protruding pattern TP2 and the pixel defining layer PDL and a second portion disposed on the pixel electrode PE, where the first portion and the second portion may be spaced apart from each other. When the charge generation layer CGL extends without being disconnected between the pixels PX, leakage current (i.e., side leakage current) may occur between the pixels PX disposed adjacent to each other. Thus, since the charge generation layer CGL is disconnected by the protruding patterns TP1 and TP2, leakage current that may occur between the pixels PX disposed adjacent to each other may be minimized.

For another example, the first common layer CL1 included in the intermediate layer ML may be disconnected by the protruding patterns TP1 and TP2. The first common layer CL1 may include a first portion disposed on the second protruding pattern TP2 and the pixel defining layer PDL and a second portion disposed on the pixel electrode PE, where the first portion and the second portion may be spaced apart from each other. When the first common layer CL1 extends without being disconnected between the pixels PX, leakage current (i.e., side leakage current) may occur between the pixels PX disposed adjacent to each other. Thus, since the first common layer CL1 is disconnected by the protruding patterns TP1 and TP2, leakage current that may occur between the pixels PX disposed adjacent to each other may be minimized.

Although FIG. 4 illustrates that the intermediate layer ML has a structure in which two light emitting layers and one charge generation layer are stacked, the invention is not limited thereto. For example, the intermediate layer ML may have a structure in which one or three or more light emitting layers or two or more charge generation layers are stacked.

In an embodiment, the common electrode CE may be disposed on the intermediate layer ML, where the common electrode CE may continuously extend into the display area DA. The common electrode CE may include a metal, an alloy, a conductive metal oxide, a conductive metal nitride, a transparent conductive material, or the like. These may be used alone or in combination with each other.

Accordingly, in an embodiment, the light emitting element LE including the pixel electrode PE, the intermediate layer ML, and the common electrode CE may be disposed on the substrate SUB.

In an embodiment, the encapsulation layer TFE may be disposed on the common electrode CE and may prevent impurities, moisture, outside air, or the like from penetrating into the light emitting element LE from the outside. The encapsulation layer TFE may include at least one inorganic encapsulation layer and at least one organic encapsulation layer.

The display device 10, according to an embodiment, may include the protection pattern PP and the protruding patterns TP1 and TP2, each exposing a portion of the pixel electrode PE. The second protruding pattern TP2 may protrude further toward the center of the pixel electrode PE than the first protruding pattern TP1, and the intermediate layer ML may be disconnected by the shape of the protruding patterns TP1 and TP2. Accordingly, leakage current that may occur between the pixels PX disposed adjacent to each other may be minimized, thereby minimizing color mixing between the pixels PX.

In addition, in an embodiment, since the protection pattern PP may be relatively thin, damage to the pixel electrode PE may be prevented while forming the protection pattern PP, thereby improving display quality of the display device 10. In addition, since each of the protruding patterns TP1 and TP2 includes an inorganic material, a path through which gas generated from an organic material included in the via insulating layer VIA flows into the intermediate layer ML may be blocked. Accordingly, deterioration of the light emitting element LE may be prevented, and pixel shrinkage may be prevented.

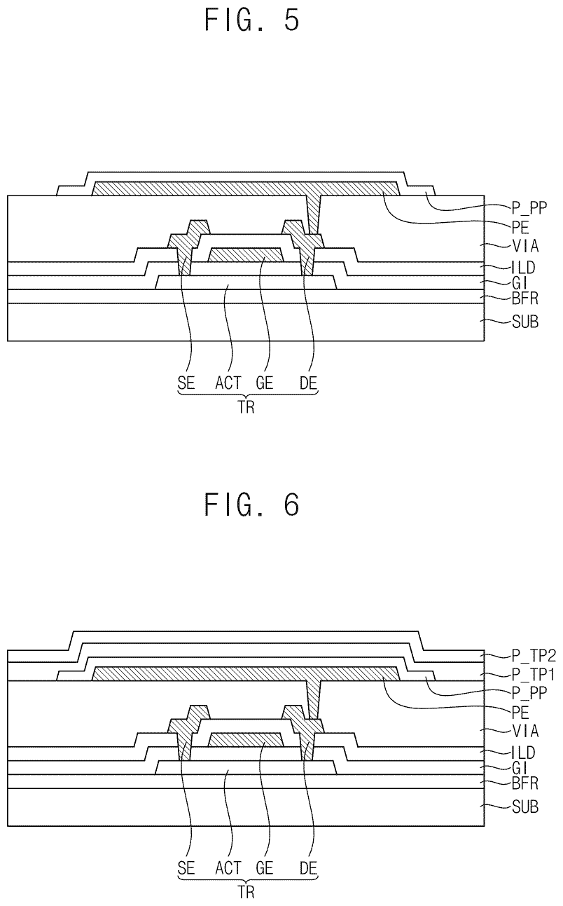

FIGS. 5, 6, 7, 8, 9, and 10 are cross-sectional views illustrating a method of manufacturing a display device, according to an embodiment.

In an embodiment, a method of manufacturing a display device described with reference to FIGS. 5, 6, 7, 8, 9, and 10 may be a method of manufacturing the display device 10 described with reference to FIGS. 1, 2, 3, and 4. Hereinafter, redundant descriptions will be omitted or simplified.

In an embodiment and referring to FIG. 5, the buffer layer BFR, the active pattern ACT, the gate insulating layer GI, the gate electrode GE, the interlayer insulating layer ILD, the first electrode SE, the second electrode DE, the via insulating layer VIA, and the pixel electrode PE may be sequentially formed on the substrate SUB. A preliminary protection pattern P_PP may be formed on the pixel electrode PE.

In an embodiment, the preliminary protection pattern P_PP may be formed to cover the pixel electrode PE. For example, the preliminary protection pattern P_PP may be formed to cover the upper and side surfaces of the pixel electrode PE. The preliminary protection pattern P_PP and the pixel electrode PE may be formed through different patterning processes. In another embodiment, the preliminary protection pattern P_PP may be formed to cover the upper surface of the pixel electrode PE. The preliminary protection pattern P_PP and the pixel electrode PE may be formed through the same patterning process.

In an embodiment, the preliminary protection pattern P_PP may include a transparent conductive material. For example, the preliminary protection pattern P_PP may include indium gallium zinc oxide, indium tin oxide, indium zinc oxide, or the like.

In an embodiment, the preliminary protection pattern P_PP may include a material having an etch selectivity that is different from that of the pixel electrode PE. The preliminary protection pattern P_PP may include a metal, an alloy, or the like having an etch selectivity that is different from that of the pixel electrode PE. For example, the preliminary protection pattern P_PP may include a material having an etch selectivity that is higher than that of the pixel electrode PE with respect to an etchant that may be used when patterning the preliminary protection pattern P_PP. For example, the preliminary protection pattern P_PP may include aluminum, molybdenum, an alloy including aluminum, an alloy including molybdenum, or the like.

However, the invention is not limited thereto, and the preliminary protection pattern P_PP may include various materials that may be easily patterned while preventing damage to the pixel electrode PE.

In an embodiment and referring to FIG. 6, a preliminary first protruding pattern P_TP1 and a preliminary second protruding pattern P_TP2 may be sequentially formed on the preliminary protection pattern P_PP. The preliminary first protruding pattern P_TP1 may be formed to cover the preliminary protection pattern P_PP, and the preliminary second protruding pattern P_TP2 may be formed to cover the preliminary first protruding pattern P_TP1.

The preliminary first protruding pattern P_TP1 and the preliminary second protruding pattern P_TP2 may include an inorganic material. In an embodiment, the preliminary first protruding pattern P_TP1 and the preliminary second protruding pattern P_TP2 may include different materials. The preliminary first protruding pattern P_TP1 and the preliminary second protruding pattern P_TP2 may include materials having different etch selectivity. For example, the preliminary first protruding pattern P_TP1 may include a material having an etch selectivity that is higher than that of the preliminary second protruding pattern P_TP2 with respect to an etching gas that may be used when patterning the preliminary first protruding pattern P_TP1 and the preliminary second protruding pattern P_TP2. For example, the preliminary first protruding pattern P_TP1 may include silicon nitride and the preliminary second protruding pattern P_TP2 may include silicon oxide, but the invention is not limited thereto.

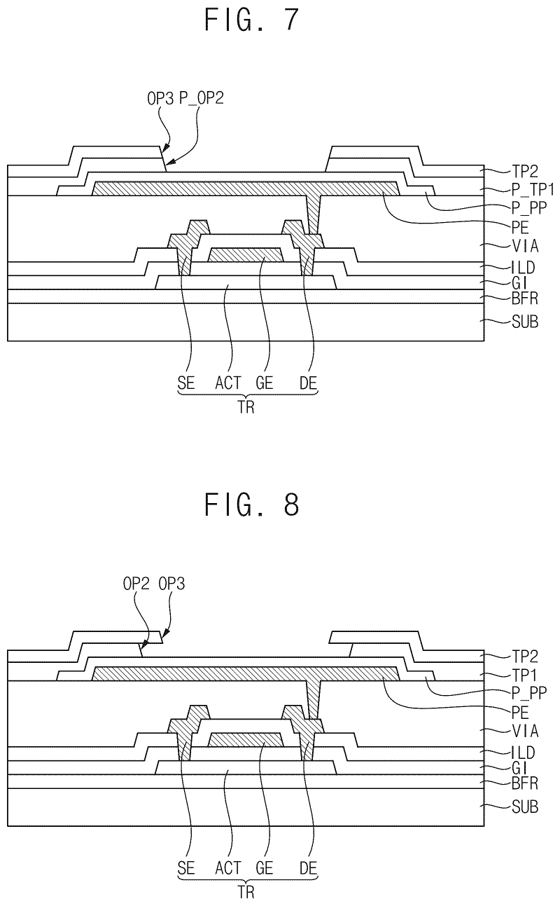

In an embodiment and referring to FIGS. 6 and 7, portions of the preliminary second protruding pattern P_TP2 and the preliminary first protruding pattern P_TP1 may be removed to form the third opening OP3 and a preliminary second opening P_OP2, respectively. That is, the second protruding pattern TP2 defining the third opening OP3 and the preliminary first protruding pattern P_TP1 defining the preliminary second opening P_OP2 may be formed. For example, the third opening OP3 and the preliminary second opening P_OP2 may be formed through dry etching. The third opening OP3 and the preliminary second opening P_OP2 may be connected. The third opening OP3 and the preliminary second opening P_OP2 may expose at least a portion of the preliminary protection pattern P_PP.

Although FIG. 7 illustrates that the preliminary second opening P_OP2 is formed to expose the preliminary protection pattern P_PP, the invention is not limited thereto. For example, the preliminary second opening P_OP2 may be formed by leaving a portion of the preliminary first protruding pattern P_TP1 on an upper surface of the preliminary protection pattern P_PP so as not to expose the preliminary protection pattern P_PP. In this case, the portion of the preliminary first protruding pattern P_TP1 left on the upper surface of the preliminary protection pattern P_PP may minimize damage to the preliminary protection pattern P_PP that protects the pixel electrode PE.

In an embodiment and referring to FIGS. 7 and 8, a portion of the preliminary first protruding pattern P_TP1 may be removed to form the second opening OP2. That is, the first protruding pattern TP1 defining the second opening OP2 may be formed. For example, the second opening OP2 may be formed through dry etching.

In this embodiment, due to a difference in etch selectivity between the second protruding pattern TP2 and the preliminary first protruding pattern P_TP1, an etch rate of the preliminary first protruding pattern P_TP1 may be relatively greater than an etch rate of the second protruding pattern TP2. Accordingly, a portion of the preliminary first protruding pattern P_TP1 disposed below the second protruding pattern TP2 may be etched to form the first protruding pattern TP1, and the second protruding pattern TP2 may be formed to protrude further toward the center of the pixel electrode PE than the first protruding pattern TP1. A degree to which the second protruding pattern TP2 protrudes further toward the center of the pixel electrode PE than the first protruding pattern TP1 may be controlled by the time during which the etching process is performed. The second opening OP2 may be connected to the third opening OP3, and may expose at least a portion of the preliminary protection pattern P_PP.

While the protruding patterns TP1 and TP2 are formed (i.e., while the preliminary first protruding pattern P_TP1 and the preliminary second protruding pattern P_TP2 are etched), damage to the pixel electrode PE may be prevented by the preliminary protection pattern P_PP disposed on the pixel electrode PE.

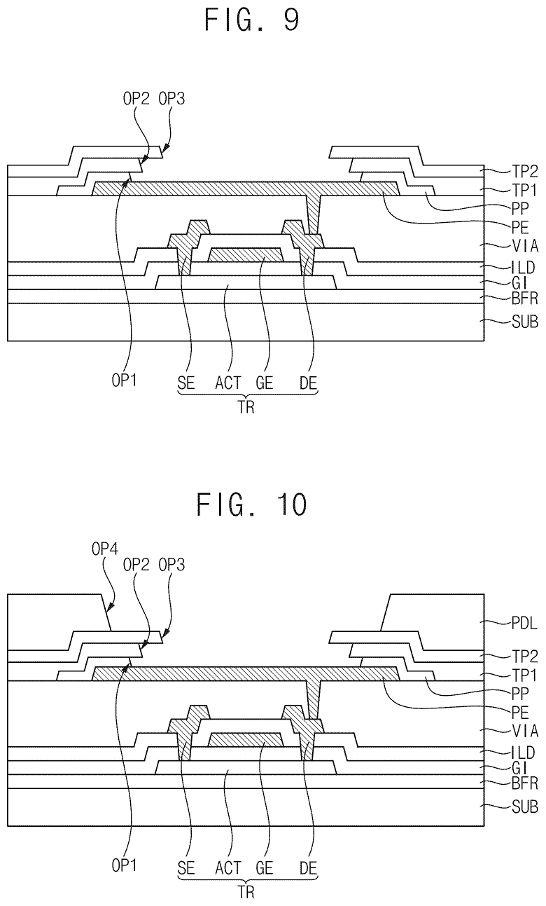

In an embodiment and referring to FIGS. 8 and 9, a portion of the preliminary protection pattern P_PP may be removed to form the first opening OP1. That is, the protection pattern PP defining the first opening OP1 may be formed. For example, the first opening OP1 may be formed through wet etching.

The protection pattern PP may be formed by etching the preliminary protection pattern P_PP exposed by the second opening OP2 and a portion of the preliminary protection pattern P_PP disposed below the first protruding pattern TP1, and the first protruding pattern TP1 may be formed to protrude further toward the center of the pixel electrode PE than the protection pattern PP. The first opening OP1 may be connected to the openings OP2 and OP3 and may expose at least a portion of the pixel electrode PE.

In an embodiment, when the preliminary protection pattern P_PP and the pixel electrode PE include materials having different etch selectivity, an etch rate of the preliminary protection pattern P_PP may be relatively greater than an etch rate of the pixel electrode PE due to a difference in the etch selectivity between the preliminary protection pattern P_PP and the pixel electrode PE. Accordingly, the protection pattern PP may be easily formed while minimizing damage to the pixel electrode PE.

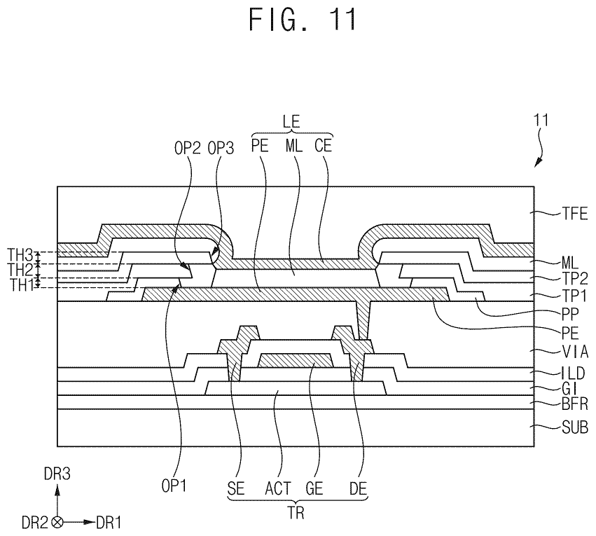

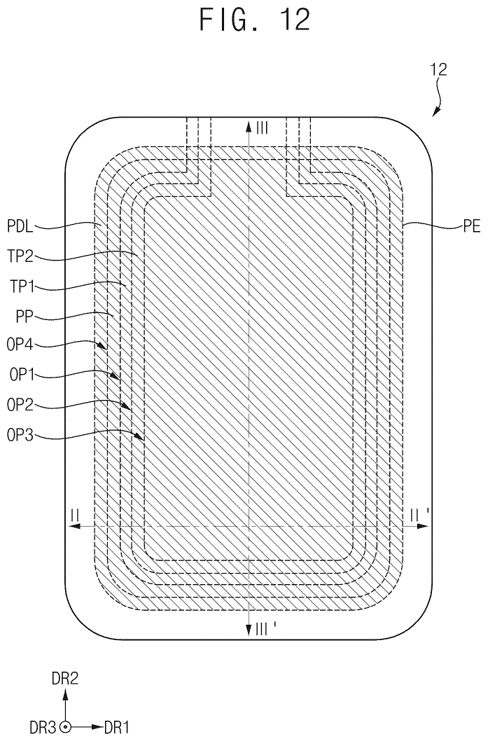

In an embodiment and referring to FIG. 10, the pixel defining layer PDL defining the fourth opening OP4 may be formed on the second protruding pattern TP2. The fourth opening OP4 may be connected to the openings OP1, OP2, and OP3, and may expose at least a portion of the pixel electrode PE and at least a portion of the second protruding pattern TP2.

Referring back to FIG. 3, the intermediate layer ML, the common electrode CE, and the encapsulation layer TFE may be sequentially formed on the pixel defining layer PDL. The intermediate layer ML may be formed to be disconnected by the protruding patterns TP1 and TP2. Accordingly, the display device 10 illustrated in FIG. 3 may be manufactured.

FIG. 11 is a cross-sectional view illustrating a display device 11, according to an embodiment. FIG. 11 may correspond to the cross-sectional view of FIG. 3.

In an embodiment, the display device 11 described with reference to FIG. 11 may be substantially the same as or similar to the display device 10 described with reference to FIGS. 1, 2, 3, and 4, except for the pixel defining layer PDL. Hereinafter, redundant descriptions will be omitted or simplified.

In an embodiment and referring to FIG. 11, the display device 11 may include a substrate SUB, a buffer layer BFR, a transistor TR, a gate insulating layer GI, an interlayer insulating layer ILD, a via insulating layer VIA, a light emitting element LE, a protection pattern PP, a first protruding pattern TP1, a second protruding pattern TP2, and an encapsulation layer TFE.

The buffer layer BFR, the transistor TR, the gate insulating layer GI, the interlayer insulating layer ILD, the via insulating layer VIA, the light emitting element LE, the protection pattern PP, the first protruding pattern TP1, and the second protruding pattern TP2 may be disposed on the substrate SUB.

The first protruding pattern TP1 may be disposed on the protection pattern PP, and the second protruding pattern TP2 may be disposed on the first protruding pattern TP1. The first protruding pattern TP1 and the second protruding pattern TP2 may define a second opening OP2 and a third opening OP3, respectively, each exposing at least a portion of the pixel electrode PE. The protruding patterns TP1 and TP2 may be disposed along an edge of the pixel electrode PE in a plan view.

In an embodiment, a second thickness TH2 of the first protruding pattern TP1 may be in a range of about 100 Å to about 3000 Å, and a third thickness TH3 of the second protruding pattern TP2 may be in a range of about 100 Å to about 1000 Å.

In an embodiment, the protruding patterns TP1 and TP2 may cover a side portion of the pixel electrode PE. For example, when a thickness of the intermediate layer ML increases (e.g., when a number of layers included in the intermediate layer ML increases), the second thickness TH2 of the first protruding pattern TP1 may be relatively thick. A sum of the second thickness TH2 of the first protruding pattern TP1 and the third thickness TH3 of the second protruding pattern TP2 may exceed about 2000 Å, but the invention is not limited thereto. Accordingly, the protruding patterns TP1 and TP2 may cover the side portion of the pixel electrode PE, and a separate pixel defining layer (e.g., the pixel defining layer PDL of FIG. 3) that covers the side portion of the pixel electrode PE may not be required.

The intermediate layer ML may be disposed on the second protruding pattern TP2 and may be disconnected by the protruding patterns TP1 and TP2. The common electrode CE and the encapsulation layer TFE may be disposed on the intermediate layer ML.

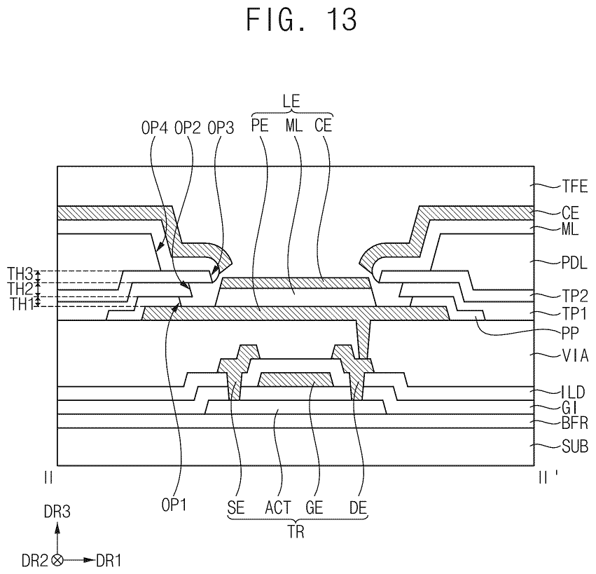

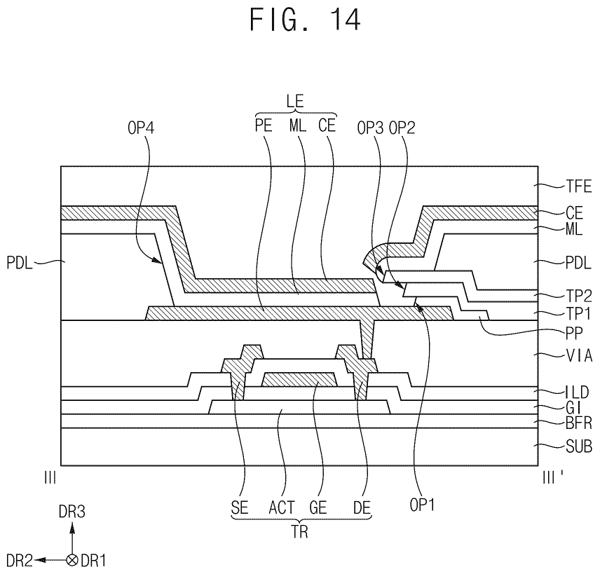

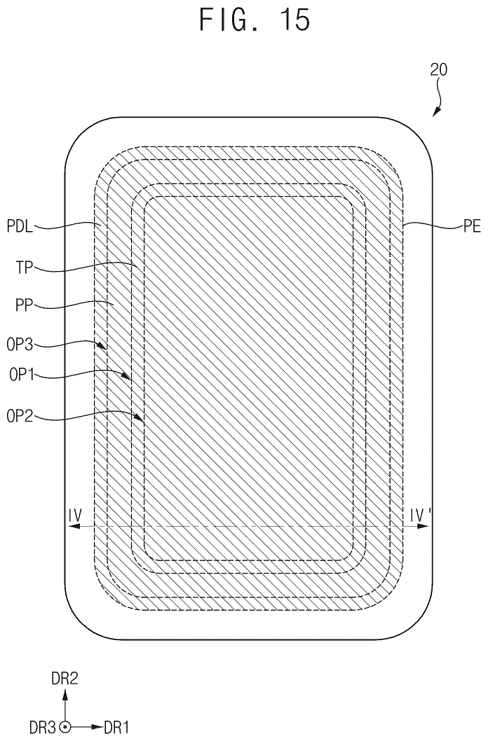

FIG. 12 is a plan view illustrating a display device 12, according to an embodiment. FIG. 12 may correspond to the plan view of FIG. 2. FIG. 13 is a cross-sectional view taken along line II-II′ of FIG. 12, according to an embodiment. FIG. 14 is a cross-sectional view taken along line III-III′ of FIG. 12, according to an embodiment.

The display device 12 described with reference to FIGS. 12, 13, and 14 may be substantially the same as or similar to the display device 10 described with reference to FIGS. 1, 2, 3, and 4, except for shapes of the openings OP1, OP2, and OP3. Hereinafter, redundant descriptions will be omitted or simplified.

In an embodiment and referring to FIGS. 12, 13, and 14, the display device 12 may include a substrate SUB, a buffer layer BFR, a transistor TR, a gate insulating layer GI, an interlayer insulating layer ILD, a via insulating layer VIA, a light emitting element LE, a protection pattern PP, a first protruding pattern TP1, a second protruding pattern TP2, a pixel defining layer PDL, and an encapsulation layer TFE.

The transistor TR may include an active pattern ACT, a gate electrode GE, a first electrode SE, and a second electrode DE, and the light emitting element LE may include a pixel electrode PE, an intermediate layer ML, and a common electrode CE.

The buffer layer BFR, the transistor TR, the gate insulating layer GI, the interlayer insulating layer ILD, the via insulating layer VIA, and the pixel electrode PE may be disposed on the substrate SUB.

The protection pattern PP may be disposed on the pixel electrode PE. In an embodiment, the protection pattern PP may define a first opening OP1 exposing at least a portion of the pixel electrode PE. For example, the protection pattern PP may include a metal, an alloy, a transparent conductive material, or the like, and a first thickness TH1 of the protection pattern PP may be about 300 Å or less.

The protection pattern PP may be disposed along an edge of the pixel electrode PE in a plan view. In an embodiment, the protection pattern PP may not overlap a partial area of the edge of the pixel electrode PE in a plan view. The protection pattern PP may define the first opening OP1 overlapping the partial area of the pixel electrode PE and may not cover a portion of the side portion of the pixel electrode PE.

The first protruding pattern TP1 may be disposed on the protection pattern PP. In an embodiment, the first protruding pattern TP1 may define a second opening OP2 exposing at least a portion of the pixel electrode PE. For example, the first protruding pattern TP1 may include silicon nitride, and a second thickness TH2 of the first protruding pattern TP1 may be in a range of about 100 Å to about 3000 Å.

The first protruding pattern TP1 may protrude further toward a center of the pixel electrode PE than the protection pattern PP. A planar area of the second opening OP2 may be smaller than a planar area of the first opening OP1.

The first protruding pattern TP1 may be disposed along the edge of the pixel electrode PE in a plan view. In an embodiment, the first protruding pattern TP1 may not overlap the partial area of the edge of the pixel electrode PE in a plan view. The first protruding pattern TP1 may define the second opening OP2 overlapping the partial area of the pixel electrode PE and may not cover the portion of the side portion of the pixel electrode PE.

The second protruding pattern TP2 may be disposed on the first protruding pattern TP1. In an embodiment, the second protruding pattern TP2 may define a third opening OP3 exposing at least a portion of the pixel electrode PE. For example, the second protruding pattern TP2 may include silicon oxide, and a third thickness TH3 of the second protruding pattern TP2 may be in a range of about 100 Å to about 1000 Å.

The second protruding pattern TP2 may protrude further toward the center of the pixel electrode PE than the first protruding pattern TP1. A planar area of the third opening OP3 may be smaller than the planar area of the second opening OP2.

The second protruding pattern TP2 may be disposed along the edge of the pixel electrode PE in a plan view. In an embodiment, the second protruding pattern TP2 may not overlap the partial area of the edge of the pixel electrode PE in a plan view. The second protruding pattern TP2 may define the third opening OP3 overlapping the partial area of the pixel electrode PE and may not cover the portion of the side portion of the pixel electrode PE.

The pixel defining layer PDL may be disposed on the via insulating layer VIA and the second protruding pattern TP2. In an embodiment, the pixel defining layer PDL may define a fourth opening OP4 exposing at least a portion of the pixel electrode PE and at least a portion of the second protruding pattern TP2.

The pixel defining layer PDL may be disposed along the edge of the pixel electrode PE in a plan view and may cover the portion of the side portion of the pixel electrode PE. The pixel defining layer PDL may cover the side portion of the pixel electrode PE as a whole and the pixel defining layer PDL may overlap the partial area of the edge of the pixel electrode PE that does not overlap the protection pattern PP and the protruding patterns TP1 and TP2 in a plan view.

That is, in an embodiment, each of the protection pattern PP and the protruding patterns TP1 and TP2 may partially cover the edge of the pixel electrode PE, and the pixel defining layer PDL may entirely cover the edge of the pixel electrode PE.

The intermediate layer ML may be disposed on the pixel electrode PE, the second protruding pattern TP2, and the pixel defining layer PDL. The intermediate layer ML may be disposed on the pixel electrode PE exposed by the openings OP1, OP2, OP3, and OP4, and the second protruding pattern TP2 exposed by the fourth opening OP4 and the pixel defining layer PDL.

In an embodiment, the intermediate layer ML may be partially disconnected by the protruding patterns TP1 and TP2 and may include a first portion disposed on the second protruding pattern TP2 and a second portion disposed on the pixel electrode PE. The first portion and the second portion may be spaced apart from each other. The second portion may overlap the partial area of the edge of the pixel electrode PE that does not overlap the protection pattern PP and the protruding patterns TP1 and TP2 in a plan view. The second portion may extend from an upper surface of the pixel electrode PE to an upper surface of the pixel defining layer PDL overlapping the partial area. That is, the intermediate layer ML may be disconnected in an area overlapping the protruding patterns TP1 and TP2 in a plan view and may not be disconnected in an area not overlapping the protruding patterns TP1 and TP2 in a plan view.

The common electrode CE may be disposed on the intermediate layer ML. In an embodiment, the common electrode CE may be partially disconnected by the protruding patterns TP1 and TP2 and may include a third portion disposed on the second protruding pattern TP2 and a fourth portion disposed on the pixel electrode PE. The third portion and the fourth portion may be spaced apart from each other. The fourth portion may overlap the partial area of the edge of the pixel electrode PE that does not overlap the protection pattern PP and the protruding patterns TP1 and TP2 in a plan view. That is, the common electrode CE may be disconnected in an area overlapping the protruding patterns TP1 and TP2 in a plan view, and may not be disconnected in an area not overlapping the protruding patterns TP1 and TP2 in a plan view.

When the first protruding pattern TP1 is relatively thick, the intermediate layer ML and the common electrode CE may be disconnected together by the protruding patterns TP1 and TP2. When the common electrode CE is disconnected, voltage provided to the common electrode CE may be dropped. Thus, by forming the protection pattern PP and the protruding patterns TP1, TP2 to not cover the partial area of the edge of the pixel electrode PE, an area in which the common electrode CE is not disconnected may be formed. Accordingly, the common electrode CE may continuously extend into a display area (e.g., the display area DA of FIG. 1).

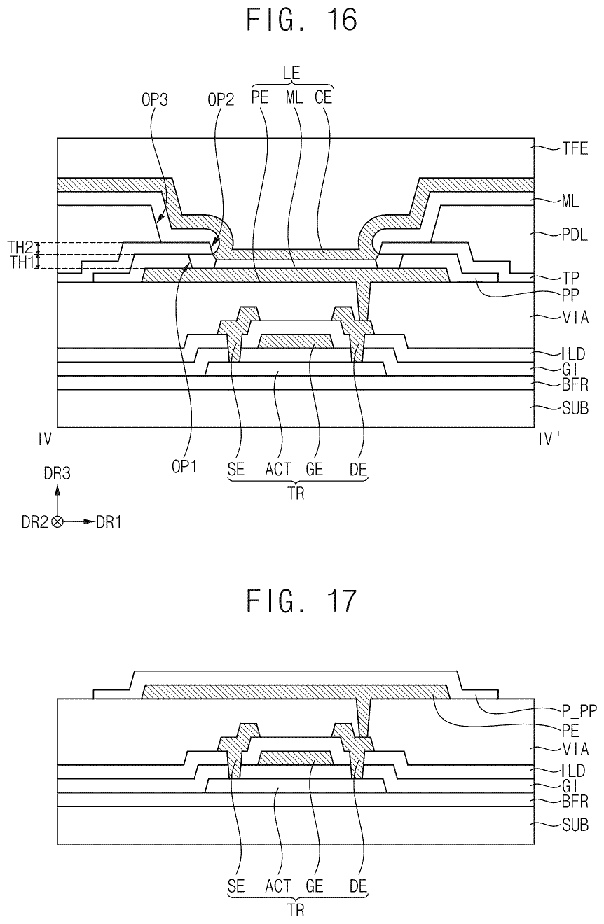

FIG. 15 is a plan view illustrating a display device 20, according to an embodiment. FIG. 15 may correspond to the plan view of FIG. 2. FIG. 16 is a cross-sectional view taken along line IV-IV′ of FIG. 15, according to an embodiment.

Hereinafter, descriptions overlapping the display device 10 described with reference to FIGS. 1, 2, 3, and 4 will be omitted or simplified.

In an embodiment and referring to FIGS. 15 and 16, the display device 20 may include a substrate SUB, a buffer layer BFR, a transistor TR, a gate insulating layer GI, an interlayer insulating layer ILD, a via insulating layer VIA, a light emitting element LE, a protection pattern PP, a protruding pattern TP, a pixel defining layer PDL, and an encapsulation layer TFE.

The transistor TR may include an active pattern ACT, a gate electrode GE, a first electrode SE, and a second electrode DE, and the light emitting element LE may include a pixel electrode PE, an intermediate layer ML, and a common electrode CE.

The buffer layer BFR, the transistor TR, the gate insulating layer GI, the interlayer insulating layer ILD, the via insulating layer VIA, and the pixel electrode PE may be disposed on the substrate SUB.

The protection pattern PP may be disposed on the pixel electrode PE. In an embodiment, the protection pattern PP may define a first opening OP1 exposing at least a portion of the pixel electrode PE. The protection pattern PP may be disposed along an edge of the pixel electrode PE in a plan view. In an embodiment, the protection pattern PP may cover a portion of an upper surface (e.g., an edge of the upper surface) and a side surface of the pixel electrode PE. In another embodiment, the protection pattern PP may cover only a portion of the upper surface of the pixel electrode PE.

In an embodiment, the protection pattern PP may include a transparent conductive material. For example, the protection pattern PP may include indium gallium zinc oxide, indium tin oxide, indium zinc oxide, or the like.

In an embodiment, the protection pattern PP may include a material having an etch selectivity that is different from that of the pixel electrode PE. The protection pattern PP may include a metal, an alloy, or the like having an etch selectivity that is different from that of the pixel electrode PE. For example, the protection pattern PP may include a material having an etch selectivity that is higher than that of the pixel electrode PE with respect to an etchant that may be used when forming the protection pattern PP. For example, the protection pattern PP may include aluminum, molybdenum, an alloy including aluminum, an alloy including molybdenum, or the like.

However, the invention is not limited thereto, and the protection pattern PP may include various materials that may be easily formed while preventing damage to the pixel electrode PE during a manufacturing process of the display device 20.

In an embodiment, a first thickness TH1 of the protection pattern PP may be in a range of about 100 Å to about 3000 Å. Here, the first thickness TH1 of the protection pattern PP may be a length of the protection pattern PP directed in the third direction DR3. However, the invention is not limited thereto, and the first thickness TH1 of the protection pattern PP may be adjusted depending on a material included in the intermediate layer ML, a structure of the intermediate layer ML, or the like. For example, when a thickness of the intermediate layer ML increases (e.g., when a number of layers included in the intermediate layer ML increases), the first thickness TH1 of the protection pattern PP may exceed about 3000 Å.

The protruding pattern TP may be disposed on the protection pattern PP. In an embodiment, the protruding pattern TP may define a second opening OP2 exposing at least a portion of the pixel electrode PE, where the second opening OP2 may be connected to the first opening OP1. The protruding pattern TP may be disposed along the edge of the pixel electrode PE in a plan view.

In an embodiment, the protruding pattern TP may protrude further toward a center of the pixel electrode PE than the protection pattern PP. A side surface of the protruding pattern TP defining the second opening OP2 may protrude further toward the center of the pixel electrode PE than a side surface of the protection pattern PP defining the first opening OP1. The side surface of the protruding pattern TP and the side surface of the protection pattern PP may have a step difference. A planar area of the second opening OP2 may be smaller than a planar area of the first opening OP1. For example, the protruding pattern TP may cover an upper surface of the protection pattern PP. Accordingly, the protection pattern PP and the protruding pattern TP may form a tip shape (or an eave shape) in a cross-sectional view.

In an embodiment, the protruding pattern TP may include an inorganic material. For example, the protruding pattern TP may include silicon nitride, silicon oxide, or the like, but the invention is not limited thereto. The protruding pattern TP may have a single-layer structure or multi-layer structure.

In an embodiment, a second thickness TH2 of the protruding pattern TP may be in a range of about 100 Å to about 1000 Å, but the invention is not limited thereto. Here, the second thickness TH2 of the protruding pattern TP may be a length of the protruding pattern TP directed in the third direction DR3. For example, when the third thickness TH3 of the protruding pattern TP is greater than about 1000 Å, a profile of the protruding pattern TP may affect upper components.

The pixel defining layer PDL may be disposed on the protruding pattern TP. In an embodiment, the pixel defining layer PDL may define a third opening OP3 exposing at least a portion of the pixel electrode PE, where the third opening OP3 may be connected to the first opening OP1 and the second opening OP2. The pixel defining layer PDL may be disposed along the edge of the pixel electrode PE in a plan view. The pixel defining layer PDL may cover a side portion of the pixel electrode PE and may include an organic material such as a polyimide resin, an epoxy resin, a siloxane resin, or the like. These may be used alone or in combination with each other.

In an embodiment, the third opening OP3 may further expose at least a portion of the protruding pattern TP, where the protruding pattern TP may protrude further toward the center of the pixel electrode PE than the pixel defining layer PDL. The side surface of the protruding pattern TP defining the second opening OP2 may protrude further toward the center of the pixel electrode PE than a side surface of the pixel defining layer PDL defining the third opening OP3. A planar area of the third opening OP3 may be greater than the planar area of the second opening OP2. In addition, the planar area of the third opening OP3 may be greater than the planar area of the first opening OP1.

In an embodiment, the intermediate layer ML may be disposed on the pixel electrode PE, the protruding pattern TP, and the pixel defining layer PDL. The intermediate layer ML may be disposed on the pixel electrode PE exposed by the openings OP1, OP2, and OP3, the protruding pattern TP exposed by the third opening OP3, and the pixel defining layer PDL.

In an embodiment, the intermediate layer ML may have a multi-layer structure. For example, the intermediate layer ML may include a common layer, a light emitting layer, a charge generation layer, or the like.

In an embodiment, the intermediate layer ML may be disconnected by the protection pattern PP and the protruding pattern TP. The intermediate layer ML may be disconnected by the shapes of the protection pattern PP and the protruding pattern TP. The intermediate layer ML may include a first portion disposed on the protruding pattern TP and the pixel defining layer PDL and a second portion disposed on the pixel electrode PE, where the first portion and the second portion may be spaced apart from each other. Since the intermediate layer ML is disconnected between pixels disposed adjacent to each other, leakage current that may occur between pixels adjacent to each other may be minimized.

In an embodiment, the common electrode CE may be disposed on the intermediate layer ML and may continuously extend into a display area. The encapsulation layer TFE may be disposed on the common electrode CE.

The display device 20, according to an embodiment, may include the protection pattern PP and the protruding pattern TP, each exposing a portion of the pixel electrode PE. The protruding pattern TP may protrude further toward the center of the pixel electrode PE than the protection pattern PP, and the intermediate layer ML may be disconnected by the shape of the protection pattern PP and the protruding pattern TP. Accordingly, leakage current that may occur between the pixels disposed adjacent to each other may be minimized, thereby minimizing color mixing between the pixels. In addition, since the protruding pattern TP includes an inorganic material, a path through which gas generated from an organic material included in the via insulating layer VIA flows into the intermediate layer ML may be blocked. Accordingly, deterioration of the light emitting element LE may be prevented, and pixel shrinkage may be prevented.

FIGS. 17, 18, 19, 20, and 21 are cross-sectional views illustrating a method of manufacturing a display device, according to an embodiment.

A method of manufacturing a display device described with reference to FIGS. 17, 18, 19, 20, and 21 may be a method of manufacturing the display device 20 described with reference to FIGS. 15 and 16. Hereinafter, redundant descriptions will be omitted or simplified.

In an embodiment and referring to FIG. 17, the buffer layer BFR, the active pattern ACT, the gate insulating layer GI, the gate electrode GE, the interlayer insulating layer ILD, the first electrode SE, the second electrode DE, the via insulating layer VIA, and the pixel electrode PE may be sequentially formed on the substrate SUB. A preliminary protection pattern P_PP may be formed on the pixel electrode PE.

In an embodiment, the preliminary protection pattern P_PP may be formed to cover the pixel electrode PE. For example, the preliminary protection pattern P_PP may be formed to cover the upper and side surfaces of the pixel electrode PE, where the preliminary protection pattern P_PP and the pixel electrode PE may be formed through different patterning processes. For another example, the preliminary protection pattern P_PP may be formed to cover the upper surface of the pixel electrode PE. where the preliminary protection pattern P_PP and the pixel electrode PE may be formed through the same patterning process.

In an embodiment, the preliminary protection pattern P_PP may include a transparent conductive material. For example, the preliminary protection pattern P_PP may include indium gallium zinc oxide, indium tin oxide, indium zinc oxide, or the like.

In an embodiment, the preliminary protection pattern P_PP may include a material having an etch selectivity that is different from that of the pixel electrode PE. The preliminary protection pattern P_PP may include a metal, an alloy, or the like having an etch selectivity that is different from that of the pixel electrode PE. For example, the preliminary protection pattern P_PP may include a material having an etch selectivity that is higher than that of the pixel electrode PE with respect to an etchant that may be used when patterning the preliminary protection pattern P_PP. For example, the preliminary protection pattern P_PP may include aluminum, molybdenum, an alloy including aluminum, an alloy including molybdenum, or the like.

However, the invention is not limited thereto, and the preliminary protection pattern P_PP may include various materials that may be easily patterned while preventing damage to the pixel electrode PE.

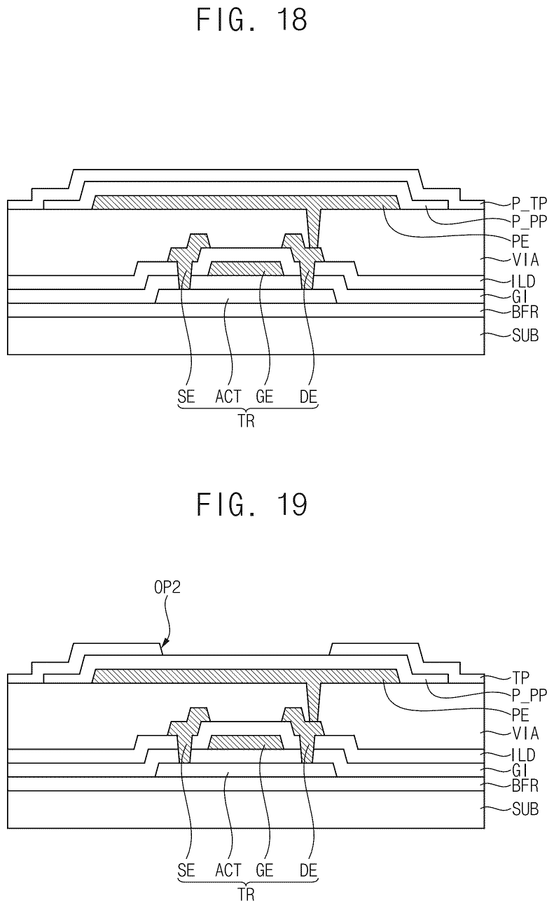

In an embodiment and referring to FIG. 18, a preliminary protruding pattern P_TP may be formed on the preliminary protection pattern P_PP. The preliminary protruding pattern P_TP may be formed to cover the preliminary protection pattern P_PP.

The preliminary protruding pattern P_TP may include an inorganic material. For example, the preliminary protruding pattern P_TP may include silicon nitride, silicon oxide, or the like, but the invention is not limited thereto.

In an embodiment and referring to FIGS. 18 and 19, a portion of the preliminary protruding pattern P_TP may be removed to form the second opening OP2. That is, the protruding pattern TP defining the second opening OP2 may be formed. For example, the second opening OP2 may be formed through dry etching. The second opening OP2 may expose at least a portion of the preliminary protection pattern P_PP.

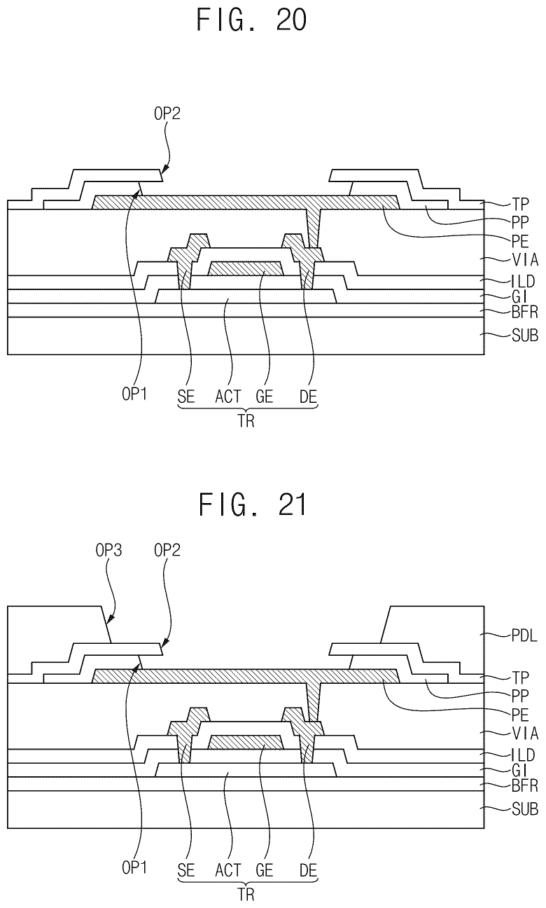

In an embodiment and referring to FIGS. 19 and 20, a portion of the preliminary protection pattern P_PP may be removed to form the first opening OP1. That is, the protection pattern PP defining the first opening OP1 may be formed. For example, the first opening OP1 may be formed through wet etching.

The preliminary protection pattern P_PP exposed by the second opening OP2 and a portion of the preliminary protection pattern P_PP disposed below the protruding pattern TP may be etched to form the protection pattern PP, and the protruding pattern TP may be formed to protrude further toward a center of the pixel electrode PE than the protection pattern PP. The first opening OP1 may be connected to the second opening OP2 and may expose at least a portion of the pixel electrode PE.

In an embodiment, when the preliminary protection pattern P_PP and the pixel electrode PE include materials having different etch selectivity, an etch rate of the preliminary protection pattern P_PP may be relatively greater than an etch rate of the pixel electrode PE due to a difference in the etch selectivity between the preliminary protection pattern P_PP and the pixel electrode PE. Accordingly, the protection pattern PP may be easily formed while minimizing damage to the pixel electrode PE.

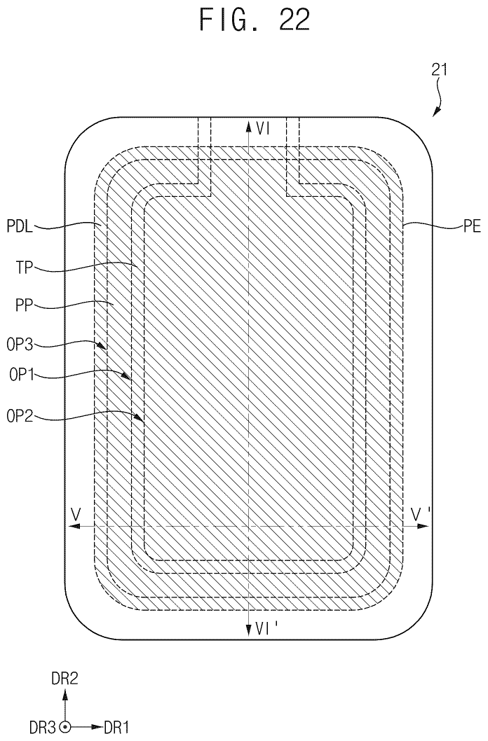

In an embodiment and referring to FIG. 21, the pixel defining layer PDL defining the third opening OP3 may be formed on the protruding pattern TP, where the third opening OP3 may be connected to the openings OP1 and OP2, and may expose at least a portion of the pixel electrode PE and at least a portion of the protruding pattern TP.

Referring back to FIG. 16, the intermediate layer ML, the common electrode CE, and the encapsulation layer TFE may be sequentially formed on the pixel defining layer PDL. The intermediate layer ML may be formed to be disconnected by the protection pattern PP and the protruding pattern TP. Accordingly, the display device 20 illustrated in FIG. 16 may be manufactured.

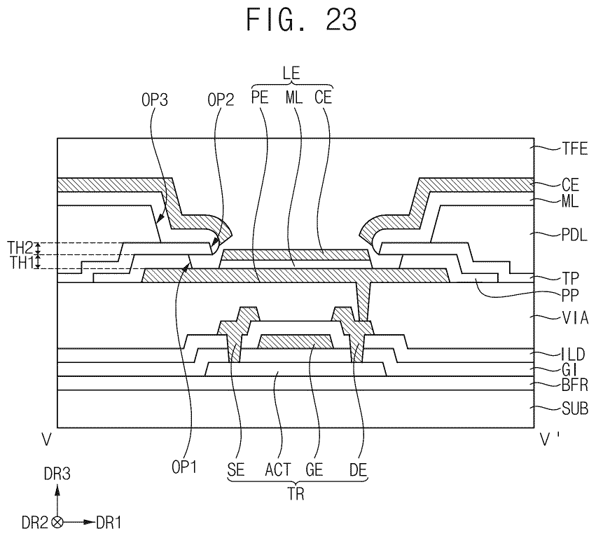

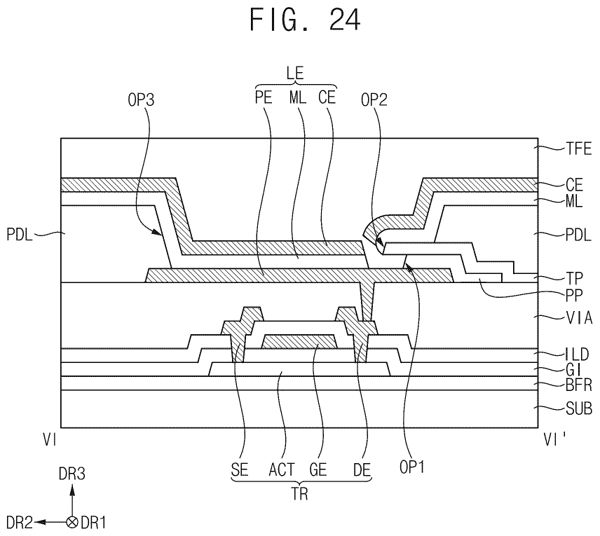

FIG. 22 is a plan view illustrating a display device 21, according to an embodiment. FIG. 22 may correspond to the plan view of FIG. 2. FIG. 23 is a cross-sectional view taken along line V-V′ of FIG. 22, according to an embodiment. FIG. 24 is a cross-sectional view taken along line VI-VI′ of FIG. 22, according to an embodiment.

The display device 21 described with reference to FIGS. 22, 23, and 24 may be substantially the same as or similar to the display device 20 described with reference to FIGS. 15, 16, 17, 18, 19, 20, and 21 except for shapes of the openings OP1 and OP2. Hereinafter, redundant descriptions will be omitted or simplified.

In an embodiment and referring to FIGS. 22, 23, and 24, the display device 21 may include a substrate SUB, a buffer layer BFR, a transistor TR, a gate insulating layer GI, an interlayer insulating layer ILD, a via insulating layer VIA, a light emitting element LE, a protection pattern PP, a protruding pattern TP, a pixel defining layer PDL, and an encapsulation layer TFE.

The transistor TR may include an active pattern ACT, a gate electrode GE, a first electrode SE, and a second electrode DE, and the light emitting element LE may include a pixel electrode PE, an intermediate layer ML, and a common electrode CE.

The buffer layer BFR, the transistor TR, the gate insulating layer GI, the interlayer insulating layer ILD, the via insulating layer VIA, and the pixel electrode PE may be disposed on the substrate SUB.

The protection pattern PP may be disposed on the pixel electrode PE. In an embodiment, the protection pattern PP may define a first opening OP1 exposing at least a portion of the pixel electrode PE. For example, the protection pattern PP may include a metal, an alloy, a transparent conductive material, or the like, and a first thickness TH1 of the protection pattern PP may be in a range of about 100 Å to about 3000 Å.

The protection pattern PP may be disposed along an edge of the pixel electrode PE in a plan view. In an embodiment, the protection pattern PP may not overlap a partial area of the edge of the pixel electrode PE in a plan view. The protection pattern PP may define the first opening OP1 overlapping the partial area of the pixel electrode PE and may not cover a portion of a side portion of the pixel electrode PE.

The protruding pattern TP may be disposed on the protection pattern PP. In an embodiment, the protruding pattern TP may define a second opening OP2 exposing at least a portion of the pixel electrode PE. For example, the protruding pattern TP may include an inorganic material such as silicon nitride, silicon oxide, or the like, and a second thickness TH2 of the protruding pattern TP may be in a range of about 100 Å to about 1000 Å.

The protruding pattern TP may protrude further toward a center of the pixel electrode PE than the protection pattern PP and a planar area of the second opening OP2 may be smaller than a planar area of the first opening OP1.

The protruding pattern TP may be disposed along the edge of the pixel electrode PE in a plan view. In an embodiment, the protruding pattern TP may not overlap the partial area of the edge of the pixel electrode PE in a plan view. The protruding pattern TP may define the second opening OP2 overlapping the partial area of the pixel electrode PE, where the protruding pattern TP may not cover the portion of the side portion of the pixel electrode PE.

The pixel defining layer PDL may be disposed on the via insulating layer VIA and the protruding pattern TP. In an embodiment, the pixel defining layer PDL may define a third opening OP3 exposing at least a portion of the pixel electrode PE and at least a portion of the protruding pattern TP.

The pixel defining layer PDL may be disposed along the edge of the pixel electrode PE in a plan view and may cover the portion of the side portion of the pixel electrode PE. The pixel defining layer PDL may cover the side portion of the pixel electrode PE as a whole and may overlap the partial area of the edge of the pixel electrode PE that does not overlap the protection pattern PP and the protruding pattern TP in a plan view.

That is, each of the protection pattern PP and the protruding pattern TP may partially cover the edge of the pixel electrode PE, and the pixel defining layer PDL may entirely cover the edge of the pixel electrode PE.

The intermediate layer ML may be disposed on the pixel electrode PE, the protruding pattern TP, and the pixel defining layer PDL. The intermediate layer ML may be disposed on the pixel electrode PE exposed by the openings OP1, OP2, and OP3, the protruding pattern TP exposed by the third opening OP3, and the pixel defining layer PDL.

In an embodiment, the intermediate layer ML may be partially disconnected by the protruding pattern TP and may include a first portion disposed on the protruding pattern TP and a second portion disposed on the pixel electrode PE. The first portion and the second portion may be spaced apart from each other. The second portion may overlap the partial area of the edge of the pixel electrode PE that does not overlap the protection pattern PP and the protruding pattern TP in a plan view. The second portion may extend from an upper surface of the pixel electrode PE to an upper surface of the pixel defining layer PDL overlapping the partial area. That is, the intermediate layer ML may be disconnected in an area overlapping the protruding pattern TP in a plan view, and may not be disconnected in an area not overlapping the protruding pattern TP in a plan view.

The common electrode CE may be disposed on the intermediate layer ML. In an embodiment, the common electrode CE may be partially disconnected by the protruding pattern TP and may include a third portion disposed on the protruding pattern TP and a fourth portion disposed on the pixel electrode PE. The third portion and the fourth portion may be spaced apart from each other. The fourth portion may overlap the partial area of the edge of the pixel electrode PE that does not overlap the protection pattern PP and the protruding pattern TP in a plan view. That is, the common electrode CE may be disconnected in an area overlapping the protruding pattern TP in a plan view, and may not be disconnected in an area not overlapping the protruding pattern TP in a plan view.

In an embodiment, when the protection pattern PP is relatively thick, the intermediate layer ML and the common electrode CE may be disconnected together by the protection pattern PP and the protruding pattern TP. When the common electrode CE is disconnected, a voltage provided to the common electrode CE may be dropped. Thus, by forming the protection pattern PP and the protruding pattern TP not to cover the partial area of the edge of the pixel electrode PE, an area in which the common electrode CE is not disconnected may be formed. Accordingly, the common electrode CE may continuously extend into a display area (e.g., the display area DA of FIG. 3).

The display devices 10, 11, 12, 20, and 21, according to embodiments, may be applied to various electronic devices. An electronic device, according to an embodiment, may include the display device described above, and may further include a module or device having additional functions in addition to the display device.

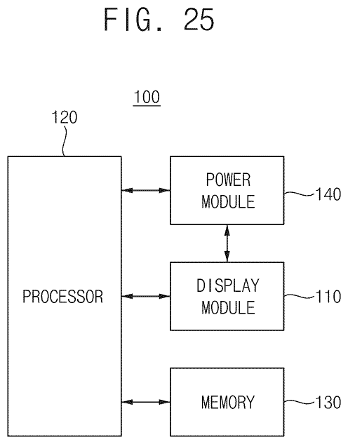

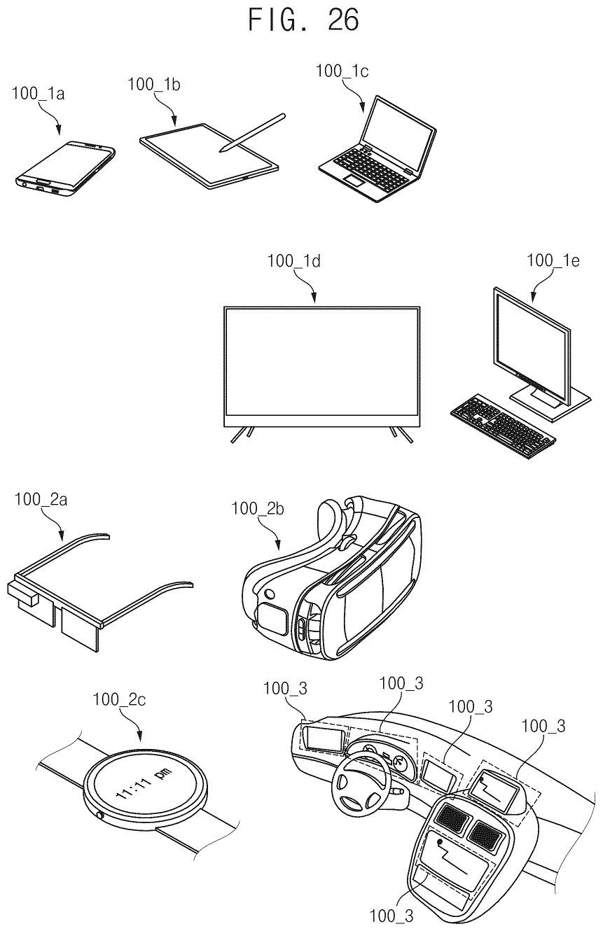

FIG. 25 is a block diagram illustrating an electronic device, according to an embodiment.

Referring to FIG. 25, an electronic device 100 may include a display module 110, a processor 120, a memory 130, and a power module 140.

The processor 120 may include at least one of a central processing unit (CPU), an application processor (AP), a graphic processing unit (GPU), a communication processor (CP), an image signal processor (ISP), and a controller.

The memory 130 may store data information necessary for an operation of the processor 120 or the display module 110. When the processor 120 executes an application stored in the memory 130, an image data signal and/or an input control signal may be transmitted to the display module 110, and the display module 110 may process the received signal and output image information through a display screen.

The power module 140 may include a power supply module such as a power adapter, a battery device, or the like and a power conversion module that converts power supplied by the power supply module to generate power necessary for an operation of the electronic device 100.

At least one of the components of the electronic device 100 described above may be included in the display device, according to an embodiment, described above. In addition, some of individual modules functionally included in one module may be included in the display device, and others may be provided separately from the display device. For example, the display device may include the display module 110, and the processor 120, the memory 130, and the power module 140 may be provided in form of other devices in the electronic device 100 other than the display device.

FIG. 26 is a schematic view illustrating electronic devices, according to embodiments.

Referring to FIG. 26, various electronic devices to which the display device, according to an embodiment, is applied may include not only an image display electronic device, but also a wearable electronic device including a display module, a vehicle electronic device 100_3 including a display module, or the like. The image display electronic device may be a smartphone 100_1a, a tablet PC 100_1b, a laptop 100_1c, a TV 100_1d, a desk monitor 100_1e, or the like. The wearable electronic device may be smart glasses 100_2a, a head mounted display 100_2b, a smart watch 100_2c, or the like. The vehicle electronic device 100_3 may be a center information display (CID) disposed on a dashboard and center fascia of a vehicle, a room mirror display, or the like.

The invention can be applied to various display devices and electronic devices. For example, the invention is applicable to various display devices such as display devices for vehicles, ships and aircraft, portable communication devices, display devices for exhibition or information transmission, medical display devices, and the like.

The foregoing is illustrative of the invention and is not to be construed as limiting thereof. Although a few embodiments have been described, those skilled in the art will readily appreciate that many modifications are possible without materially departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the invention, as well as other embodiments, are intended to be included within the scope of the invention. Moreover, the invention or parts of the invention may be combined in whole or in part without departing from the scope of the invention.

What is claimed is:

1. A display device comprising:
a protection pattern disposed on a pixel electrode and defining a first opening exposing the pixel electrode;
a first protruding pattern disposed on the protection pattern and defining a second opening exposing the pixel electrode;
a second protruding pattern disposed on the first protruding pattern, defining a third opening exposing the pixel electrode and protruding further toward a center of the pixel electrode than the first protruding pattern; and
a common electrode disposed on the second protruding pattern.

2. The display device of claim 1, wherein the first protruding pattern and the second protruding pattern include different inorganic materials.

3. The display device of claim 2, wherein
the first protruding pattern includes silicon nitride, and
the second protruding pattern includes silicon oxide.

4. The display device of claim 1, wherein the protection pattern includes at least one selected from a group consisting of a metal, an alloy, and a transparent conductive material.

5. The display device of claim 1, wherein the first protruding pattern protrudes further toward the center of the pixel electrode than the protection pattern.

6. The display device of claim 1, wherein the protection pattern, the first protruding pattern, and the second protruding pattern are disposed along an edge of the pixel electrode in a plan view.

7. The display device of claim 6, wherein the protection pattern, the first protruding pattern, and the second protruding pattern do not overlap the edge of the pixel electrode in the plan view.

8. The display device of claim 1, further comprising:
a pixel defining layer disposed between the second protruding pattern and the common electrode, wherein the pixel defining layer defines a fourth opening exposing the pixel electrode and includes an organic material.

9. The display device of claim 1, wherein a thickness of the protection pattern is in a range of about 100 Å to about 300 Å.

10. The display device of claim 1, wherein a thickness of the first protruding pattern is in a range of about 100 Å to about 3000 Å.

11. The display device of claim 1, wherein a thickness of the second protruding pattern is in a range of about 100 Å to about 1000 Å.

12. The display device of claim 1, further comprising:
an intermediate layer disposed between the second protruding pattern and the common electrode and including a charge generation layer.

13. The display device of claim 12, wherein the charge generation layer is disconnected by the first protruding pattern and the second protruding pattern.

14. The display device of claim 12, wherein the intermediate layer includes:
a first light emitting layer disposed below the charge generation layer; and
a second light emitting layer disposed on the charge generation layer.

15. A display device comprising:
a protection pattern disposed on a pixel electrode and defining a first opening exposing the pixel electrode;
a protruding pattern disposed on the protection pattern, defining a second opening exposing the pixel electrode, and protruding further toward a center of the pixel electrode than the protection pattern;
a pixel defining layer disposed on the protruding pattern and defining a third opening exposing the pixel electrode; and
a common electrode disposed on the pixel defining layer.

16. The display device of claim 15, wherein the protruding pattern includes an inorganic material.

17. The display device of claim 15, wherein the protection pattern includes at least one selected from a group consisting of a metal, an alloy, and a transparent conductive material.

18. The display device of claim 15, wherein the protection pattern and the protruding pattern are disposed along an edge of the pixel electrode in a plan view.

19. The display device of claim 18, wherein the protection pattern and the protruding pattern do not overlap the edge of the pixel electrode in the plan view.

20. The display device of claim 15, wherein a thickness of the protection pattern is in a range of about 100 Å to about 3000 Å.

21. The display device of claim 15, wherein a thickness of the protruding pattern is in a range of about 100 Å to about 1000 Å.

22. The display device of claim 15, wherein the pixel defining layer includes an organic material.

23. The display device of claim 15, further comprising:
an intermediate layer disposed between the protruding pattern and the common electrode and including a charge generation layer.

24. The display device of claim 23, wherein the charge generation layer is disconnected by the protection pattern and the protruding pattern.

25. The display device of claim 23, wherein the intermediate layer includes:
a first light emitting layer disposed below the charge generation layer; and
a second light emitting layer disposed on the charge generation layer.

26. An electronic device comprising:
a display device; and
a power module that supplies power to the display device,
wherein the display device includes:
a protection pattern disposed on a pixel electrode and defining a first opening exposing the pixel electrode;
a first protruding pattern disposed on the protection pattern and defining a second opening exposing the pixel electrode;
a second protruding pattern disposed on the first protruding pattern, defining a third opening exposing the pixel electrode and protruding further toward a center of the pixel electrode than the first protruding pattern; and
a common electrode disposed on the second protruding pattern.
